(19) United States
(12) Patent Application Publication
(10) Pub. No.: US 2009/0261416 A1
(43) Pub. Date: Oct. 22, 2009

(54) INTEGRATED MEMS DEVICE AND CONTROL CIRCUIT

(76) Inventors: Wolfgang Raberg, Sauerlach (DE); Bernhard Winkler, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/105,989

(22) Filed: Apr. 18, 2008

(51) Int. Cl. H01L 49/00; H01L 21/44

(52) U.S. Cl. 257/351; 257/350; 438/667; 257/E49.001; 257/E21.476

(57) ABSTRACT

An integrated circuit includes a silicon-on-insulator (SOI) substrate including a buried oxide layer positioned between a top-side silicon layer and a bottom-side silicon layer. A micro-electromechanical system (MEMS) device is integrated into the top-side silicon layer. A semiconductor layer is formed over the bottom-side silicon layer. A control circuit is integrated into the semiconductor layer and is configured to control the MEMS device.

### BACKGROUND

The trend to smaller and smaller microelectronic devices has led to the integration of various components into the same system. In order to realize high density integration, several approaches are typically used, including system on chip integration (SoC) or system in package integration (SiP). SoC or SiP solutions are typically used in situations where the high-density integration of components on the same chip or in the same package provides cost advantages over multi-chip solutions. The choice of which one of these approaches to use typically depends on the characteristics of the components to be integrated. Typically, SoC is used when the processing technologies (manufacturing technologies) for the components being integrated are compatible, whereas SiP is used when the processing technologies are very different (e.g., if highly integrated ASIC controllers are combined with micro-electromechanical system (MEMS) components).

Since the processing technology for a SoC solution is typically determined by the high end application, components needing only a lower quality processing technology are manufactured at a cost penalty. If this cost penalty becomes too great, an SiP approach is typically a better option. For the SiP approach, two or more chips are typically manufactured separately using the appropriate and most cost effective process technology, and then the chips are packaged together in the same package. For the SiP approach, the connections between the chips, the additional bond pads, and the typically more complex packaging technology, increase the cost of this solution. In addition, SiP solutions typically have poorer electrostatic discharge (ESD) and electromagnetic compatibility (EMC) performance than SoC solutions.

### SUMMARY

One embodiment provides an integrated circuit that includes a silicon-on-insulator (SOI) substrate. The SOI substrate includes a buried oxide layer positioned between a top-side silicon layer and a bottom-side silicon layer. A micro-electromechanical system (MEMS) device is integrated into the top-side silicon layer. A semiconductor layer is formed over the bottom-side silicon layer. A control circuit is integrated into the semiconductor layer and is configured to control the MEMS device.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating a cross-sectional view of an SOI substrate.

FIG. 2 is a diagram illustrating a cross-sectional view of a MEMS device according to one embodiment.

FIG. 3 is a diagram illustrating a cross-sectional view of the MEMS device shown in FIG. 2 with the addition of a protective cap layer according to one embodiment.

FIG. 4 is a diagram illustrating a cross-sectional view of the MEMS device shown in FIG. 3 after turning the MEMS device over for processing of the bottom-side of the device according to one embodiment.

FIG. 5 is a diagram illustrating a cross-sectional view of the MEMS device shown in FIG. 4 with the addition of a semiconductor layer according to one embodiment.

FIG. 6 is a diagram illustrating a cross-sectional view of the MEMS device shown in FIG. 5 after formation of a CMOS integrated circuit on the bottom side of the SOI substrate according to one embodiment.

FIG. 7 is a diagram illustrating a cross-sectional view of the MEMS device shown in FIG. 6 with the addition of an inter-layer dielectric (ILD) layer according to one embodiment.

FIG. 8 is a diagram illustrating a cross-sectional view of the MEMS device shown in FIG. 7 with the addition of a plurality of metallization layers according to one embodiment.

FIG. 9 is a diagram illustrating a cross-sectional view of the MEMS device shown in FIG. 8 after the formation of a plurality of vias in the bottom side of the MEMS device according to one embodiment.

FIG. 10 is a diagram illustrating a cross-sectional view of the MEMS device shown in FIG. 9 after etching the oxide layer according to one embodiment.

FIG. 11 is a diagram illustrating a cross-sectional view of the MEMS device shown in FIG. 10 after filling the vias with metal and forming additional metallization layers according to one embodiment.

FIG. 12 is a diagram illustrating a cross-sectional view of the MEMS device shown in FIG. 11 after forming a pad layer according to one embodiment.

FIG. 13 is a block diagram illustrating components contained in the MEMS device shown in FIG. 12 according to one embodiment.

FIG. 14 is a block diagram illustrating components contained in the MEMS device shown in FIG. 12 according to another embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides an integrated system that uses front and back sides of a silicon-on-insulator (SOI) substrate. In one embodiment, both sides (e.g., front and back) of an SOI wafer are used for the manufacturing of various components to produce highly integrated systems. Metal-filled vias are used in one embodiment to provide electrical connections between devices on opposing sides of the SOI wafer. In one embodiment, substantially different process technologies and doping levels are combined in the same SOI substrate, thereby enabling a high level of integration of systems that use different process technologies.

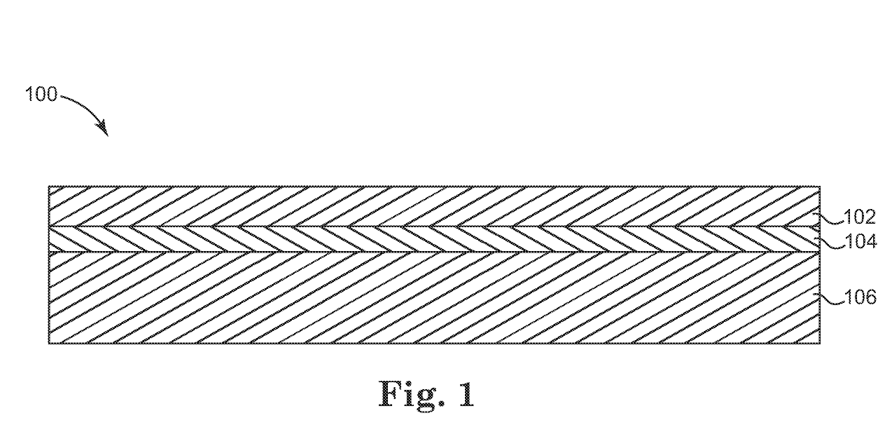

FIG. 1 is a diagram illustrating a cross-sectional view of an SOI substrate 100. SOI substrate 100 includes a buried oxide layer 104 sandwiched between two single crystal silicon layers 102 and 106. Silicon layer 102 will be referred to herein as the top-side silicon layer of substrate 100 (also referred to as the device layer), and silicon layer 106 will be referred to herein as the bottom-side silicon layer of substrate 100.

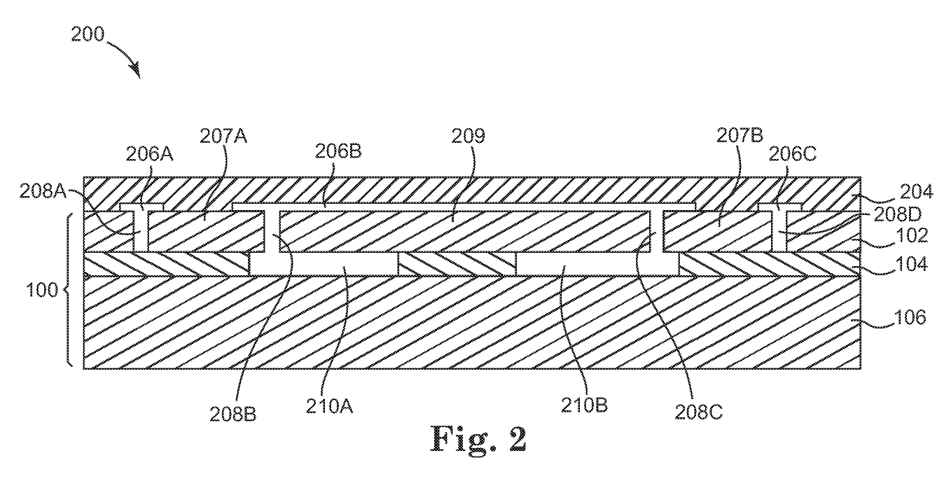

FIG. 2 is a diagram illustrating a cross-sectional view of a MEMS device 200 according to one embodiment. In the illustrated embodiment, MEMS device 200 is a silicon MEMS resonator, and is integrated into the top-side silicon layer 102 of the SOI substrate 100 shown in FIG. 1. MEMS device 200 includes SOI substrate 100, electrodes 207A and 207B, resonator structure 209, and non-conductive cap layer 204. Non-conductive cap layer 204 is formed on the top-side silicon layer 102. In one embodiment, layer 204 is a SiN layer. Resonator structure 209 is formed in the top-side silicon layer 102 of the substrate 100, and is substantially surrounded by cavities 208B, 206B, 208C, 210A, and 210B. Electrode 207A is formed in the top-side silicon layer 102 of the substrate 100, and is defined or bordered by cavities 206A, 208A, and 208B. Electrode 207B is also formed in the top-side silicon layer 102 of the substrate 100, and is defined or bordered by cavities 206C, 208C, and 208D. Cavities 206A-206C are formed in non-conductive cap layer 204. Cavities 208A-208D are formed in top-side silicon layer 102. Cavities 210A and 210B are formed in buried oxide layer 104. In one embodiment, cavities 206A-206C, 208A-208D, 210A, and 210B are formed using conventional etching or micro machining techniques.

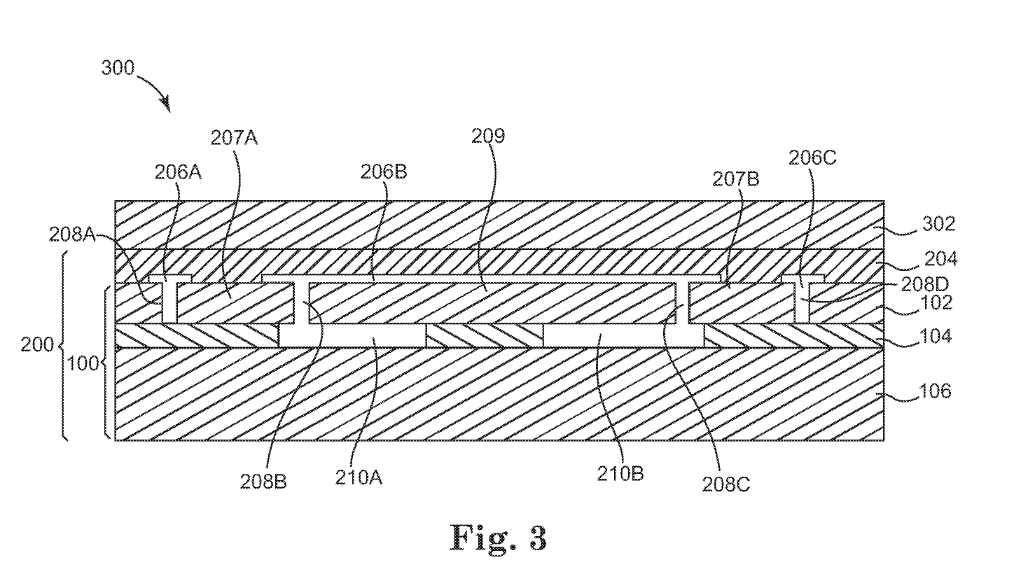

FIG. 3 is a diagram illustrating a cross-sectional view of the MEMS device 200 shown in FIG. 2 with the addition of a protective cap layer 302 according to one embodiment. The MEMS device 200 with the protective cap layer 302 is represented by reference number 300. The protective cap layer 302 is formed on the non-conductive cap layer 204. In one embodiment, the protective cap layer 302 is a silicon layer. In the illustrated embodiment, no electrical pads or contacts are provided on the top-side of the MEMS device 300 (e.g., no pads or contacts are formed over the cap layer 302).

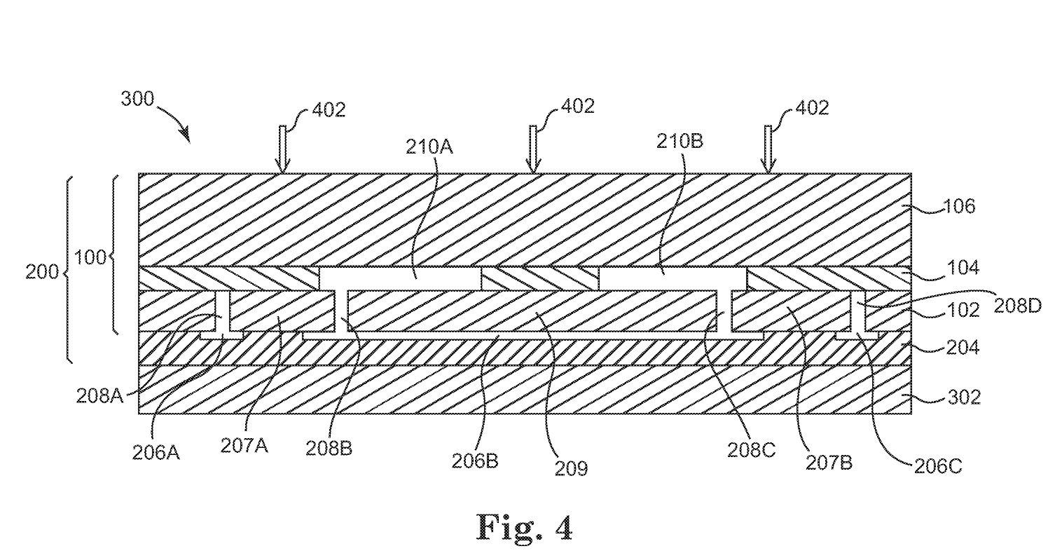

FIG. 4 is a diagram illustrating a cross-sectional view of the MEMS device 300 shown in FIG. 3 after turning the MEMS device 300 over for processing of the bottom-side of the device according to one embodiment. In one embodiment, the exposed surface of the bottom-side silicon layer 106 is cleaned prior to processing the bottom side to remove any contamination that might remain from the processing of the top-side of the device. In one embodiment, the bottom-side silicon layer 106 is thinned prior to processing the bottom side. The cleaning and/or thinning of the bottom-side silicon layer 106 is represented by arrows 402.

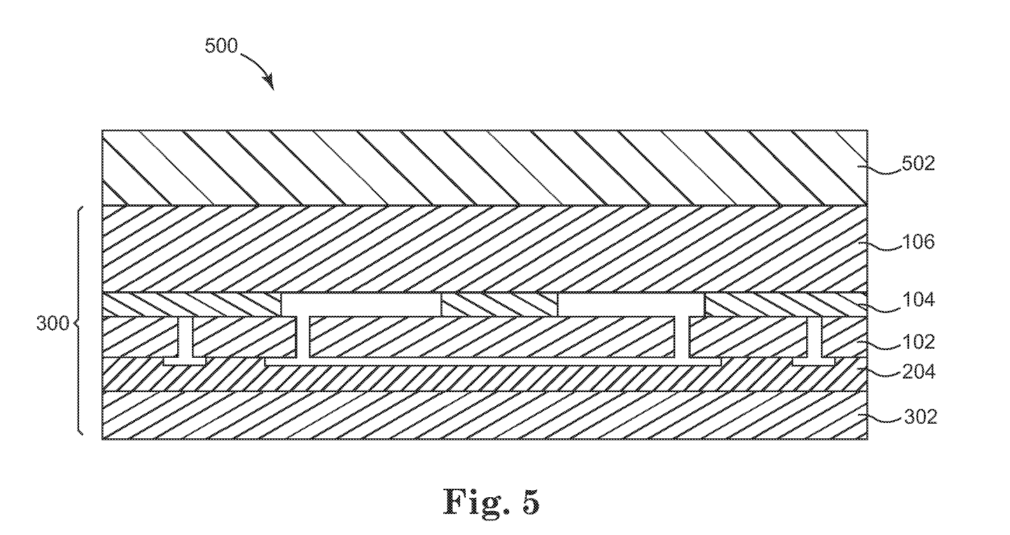

FIG. 5 is a diagram illustrating a cross-sectional view of the MEMS device 300 shown in FIG. 4 with the addition of a semiconductor layer 502 according to one embodiment. The MEMS device 300 with the semiconductor layer 502 is represented by reference number 500. The semiconductor layer 502 is formed on the bottom-side silicon layer 106. In one embodiment, the semiconductor layer 502 is an n− doped epitaxial silicon layer, and layer 502 is also referred to herein as silicon layer 502.

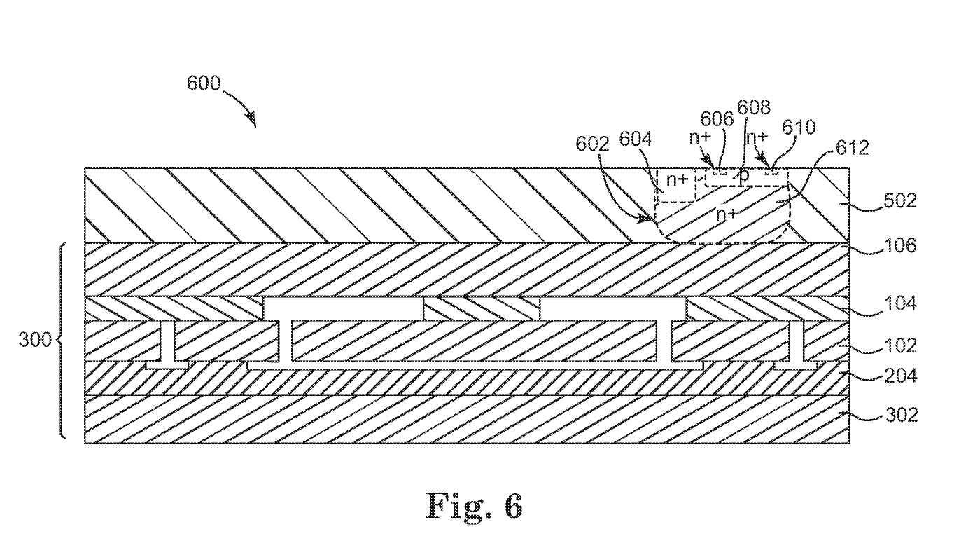

FIG. 6 is a diagram illustrating a cross-sectional view of the MEMS device 500 shown in FIG. 5 after formation of a CMOS integrated circuit 602 on the bottom side of the SOI substrate 100 according to one embodiment. The MEMS device 500 with the integrated circuit 602 is represented by reference number 600. To simplify the illustration, the integrated circuit 602 is represented in FIG. 6 by a bipolar device, which includes n+ doped buried layer 612, n+ doped regions 604, 606, and 610, and p doped region 608. In one embodiment, the integrated circuit 602 is formed in silicon layer 502 using CMOS processing. In one embodiment, integrated circuit 602 is an application specific integrated circuit (ASIC) that is configured to control the MEMS device formed on the top side of the SOI substrate 100 (e.g., MEMS resonator 200).

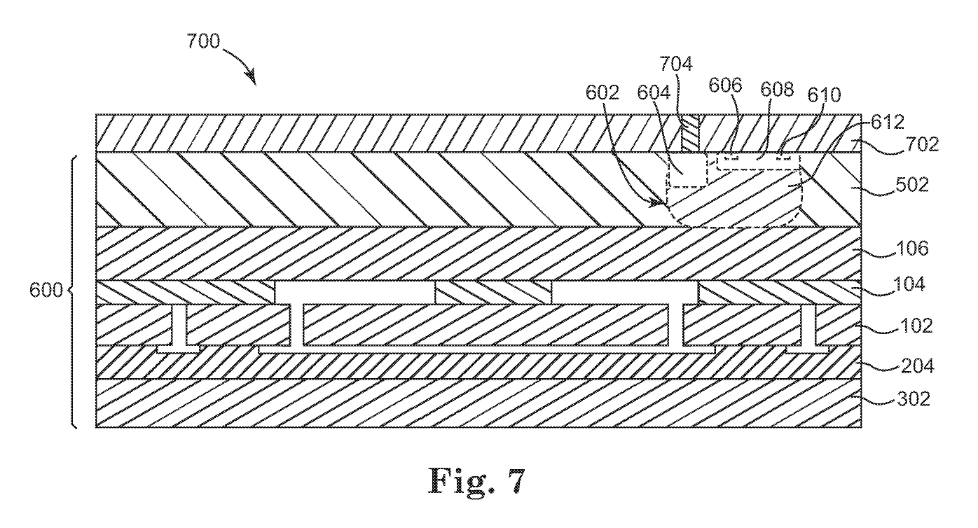

FIG. 7 is a diagram illustrating a cross-sectional view of the MEMS device 600 shown in FIG. 6 with the addition of an inter-layer dielectric (ILD) layer 702 according to one embodiment. The MEMS device 600 with the ILD layer 702 is represented by reference number 700. The ILD layer 702 is formed on the silicon layer 502. A plurality of conductors (e.g., metal conductors), such as conductor 704, are formed in ILD layer 702, and make electrical contact with the integrated circuit 602 in silicon layer 502.

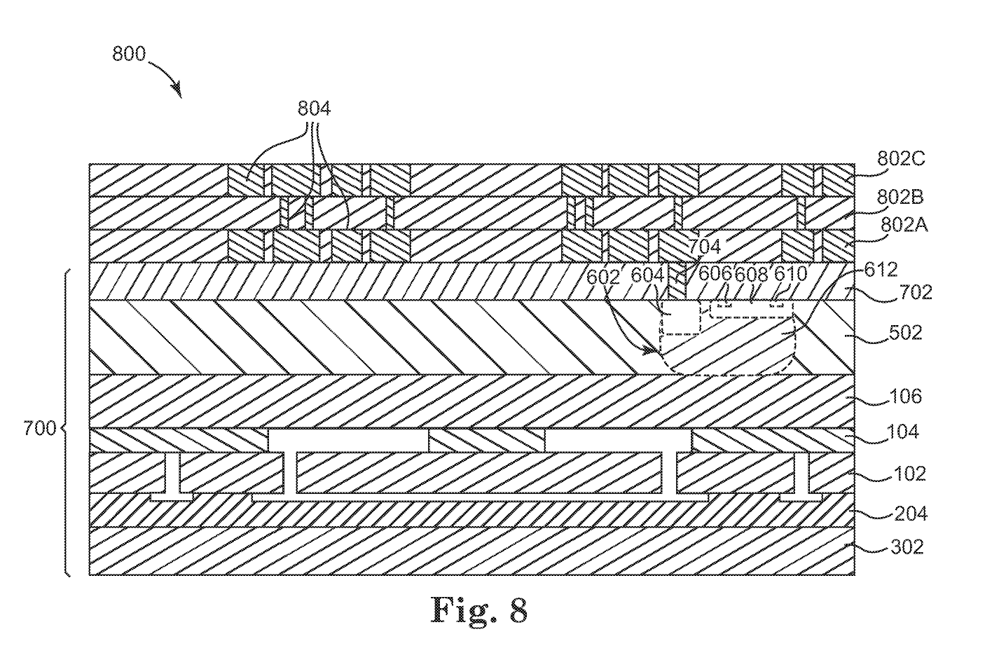

FIG. 8 is a diagram illustrating a cross-sectional view of the MEMS device 700 shown in FIG. 7 with the addition of a plurality of metallization layers 802A-802C according to one embodiment. The MEMS device 700 with the metallization layers 802A-802C is represented by reference number 800. The metallization layers 802A-802C are formed on the ILD layer 702, and include a plurality of conductors 804 (e.g., metal conductors). The conductors 804 are connected to the conductors in the ILD layer 702, such as conductor 704.

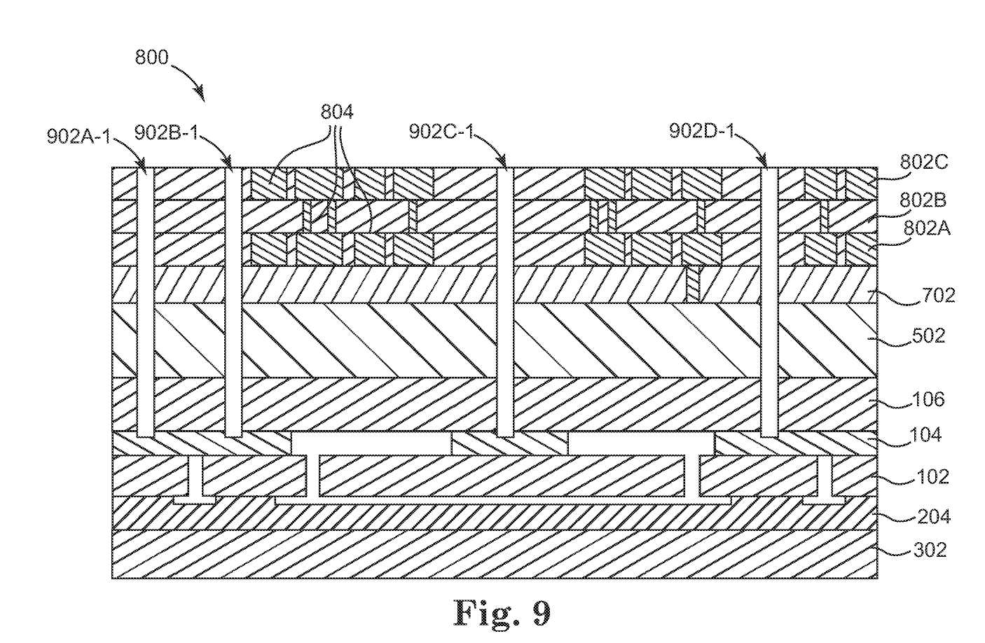

FIG. 9 is a diagram illustrating a cross-sectional view of the MEMS device 800 shown in FIG. 8 after the formation of a plurality of vias 902A-1, 902B-1, 902C-1, and 902D-1, in the bottom side of the MEMS device according to one embodiment. The integrated circuit 602 (FIGS. 6-8) has been removed in FIG. 9 to simplify the illustration. The MEMS device 800 with the vias 902A-1, 902B-1, 902C-1, and 902D-1 formed therein is represented by reference number 900. In one embodiment, the vias 902A-1, 902B-1, 902C-1, and 902D-1 are formed by etching the metallization layers 802A-802C, the ILD layer 702, and the silicon layers 502 and 106, with an etch stop at the buried oxide layer 104.

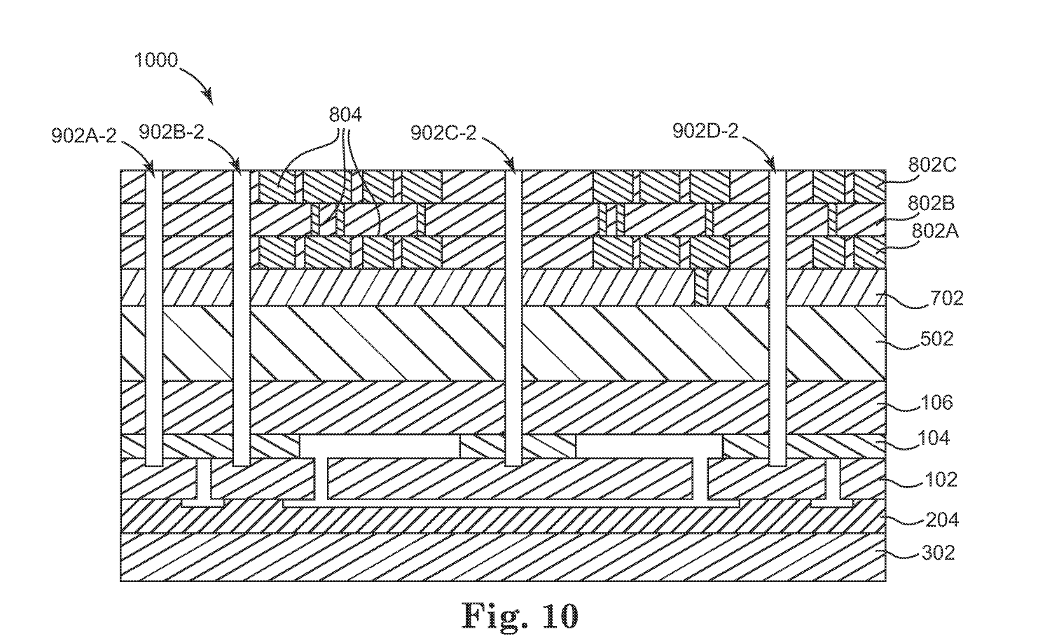

FIG. 10 is a diagram illustrating a cross-sectional view of the MEMS device 900 shown in FIG. 9 after etching the oxide layer 104 according to one embodiment. The oxide layer 104 is etched in the region of the vias 902A-1, 902B-1, 902C-1, and 902D-1, thereby forming deeper vias 902A-2, 902B-2, 902C-2, and 902D-2 that extend through the oxide layer 104. The MEMS device 900 with the vias 902A-2, 902B-2, 902C-2, and 902D-2 is represented by reference number 1000.

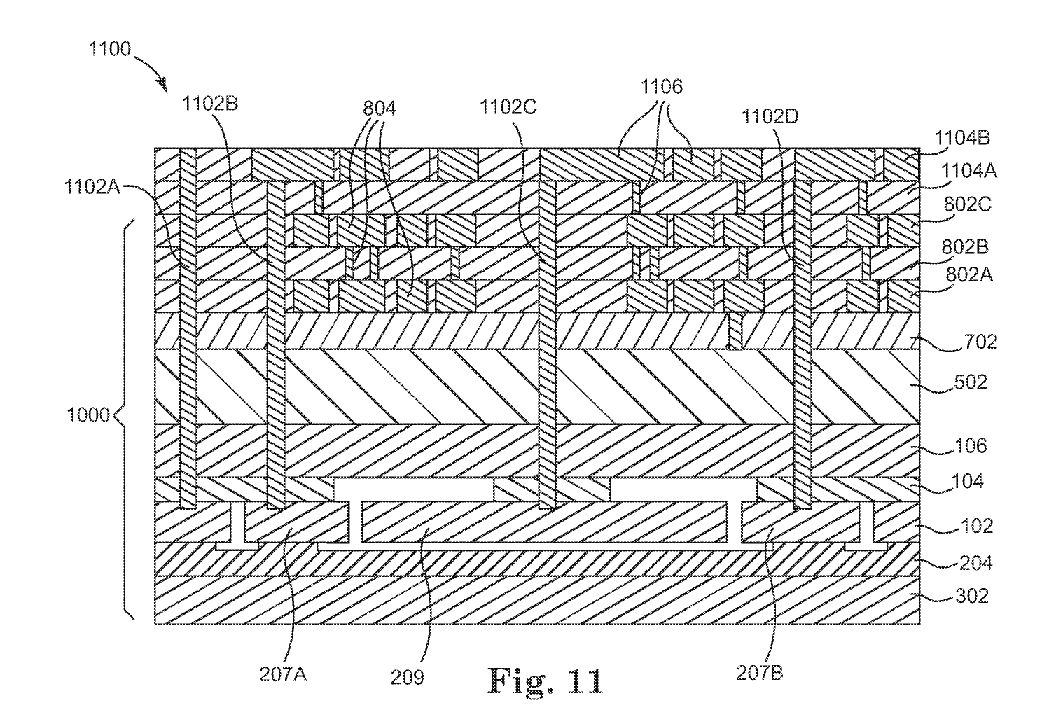

FIG. 11 is a diagram illustrating a cross-sectional view of the MEMS device 1000 shown in FIG. 10 after filling the vias 902A-2, 902B-2, 902C-2, and 902D-2 with metal and forming additional metallization layers 1104A and 1104B according to one embodiment. The MEMS device 1000 with the metal-filled vias and the additional metallization layers 1104A and 1004B is represented by reference number 1100. The metallization layers 1104A and 1104B are formed on the metallization layer 802C, and include a plurality of conductors 1106 (e.g., metal conductors). The conductors 1106 are connected to the conductors 804 in the metallization layers 802A-802C and to the metal-filled vias 1102A-1102D. As shown in FIG. 11, metal-filled via 1102A is connected to silicon layer 102; metal-filled via 1102B is connected to the electrode 207A in silicon layer 102; metal-filled via 1102C is connected to the resonator structure 209 in silicon layer 102; and metal-filled via 1102D is connected to electrode 207B in silicon layer 102.

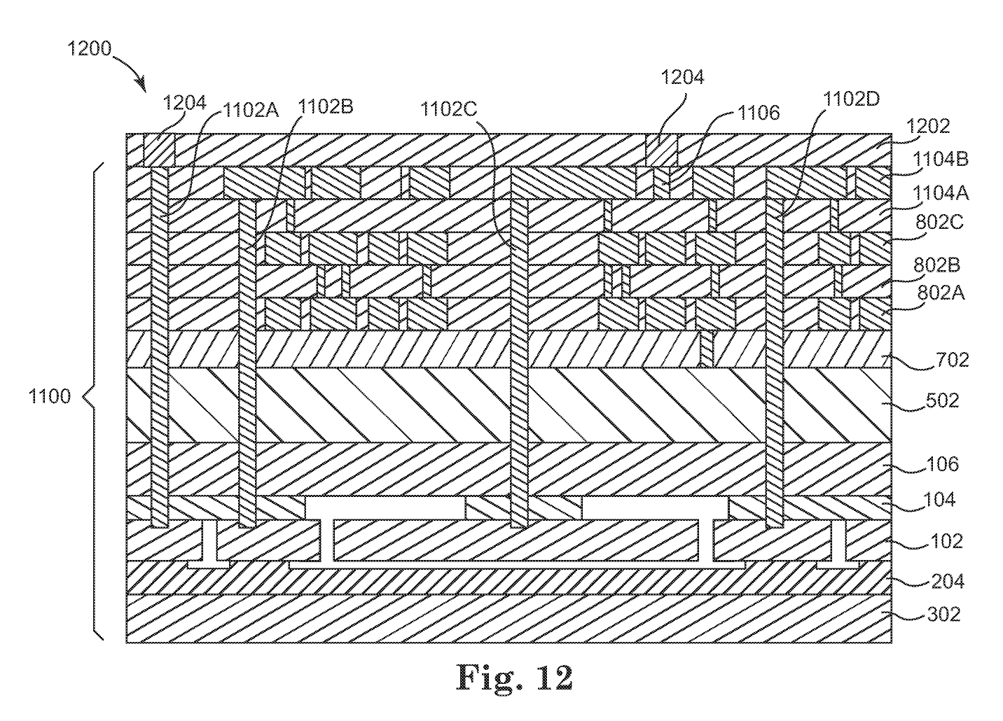

FIG. 12 is a diagram illustrating a cross-sectional view of the MEMS device 1100 shown in FIG. 11 after forming a pad layer 1202 according to one embodiment. The MEMS device 1100 with the pad layer 1202 is represented by reference number 1200. The pad layer 1202 is formed on the metallization layer 1104B, and includes a plurality of conductive pads 1204. The pads 1204 are connected to one or more of the conductors 1106 in the metallization layer 1104B and to one or more of the metal-filled vias 1102A-1102D. In the illustrated embodiment, device 1200 only includes pads 1204 on the bottom side of the device, and there are no pads located on the top side of the device. The pads 1204 provide interconnection points for electrically connecting device 1200 to other devices or circuits. MEMS device 1200 may be packaged using any suitable packaging technique, such as a package that uses wirebonds to connect pads 1204 to external package contacts. In one embodiment, MEMS device 1200 is packaged alone as a single stand-alone device. In another embodiment, MEMS device 1200 is packaged with one or more other chips.

In one embodiment, MEMS device 1200 is an integrated silicon MEMS oscillator chip with a silicon resonator (e.g., resonator 200) formed on a top side of SOI wafer 100, and a control circuit (e.g., an ASIC 602) formed on a bottom side of the SOI wafer 100 for controlling the resonator. The MEMS device 1200 according to one embodiment is implemented using two substantially different process technologies (e.g., MEMS processing for the resonator, and CMOS processing for the control circuit) and different doping levels are used for the two sides of the SOI wafer 100.

In operation according to one embodiment, the MEMS resonator 200 (FIG. 2) is driven by applying an excitation signal to a first one of the electrodes 207A or 207B (e.g., the drive electrode). In one embodiment, the excitation signal is internally generated by the control circuit (e.g., integrated circuit 602), and travels through the conductors in the metallization layers and through one of the metal-filled vias 1102B or 1102D to the electrode. Electric force interaction between the drive electrode and the resonator structure 209 causes the resonator structure 209 to vibrate at a specific frequency, which generates a sense signal on a second one of the electrodes 207A or 207B (e.g., the sense electrode). The sense signal travels through one of the metal-filled vias 1102B or 1102D and through the conductors in the metallization layers and is received by the control circuit 602.

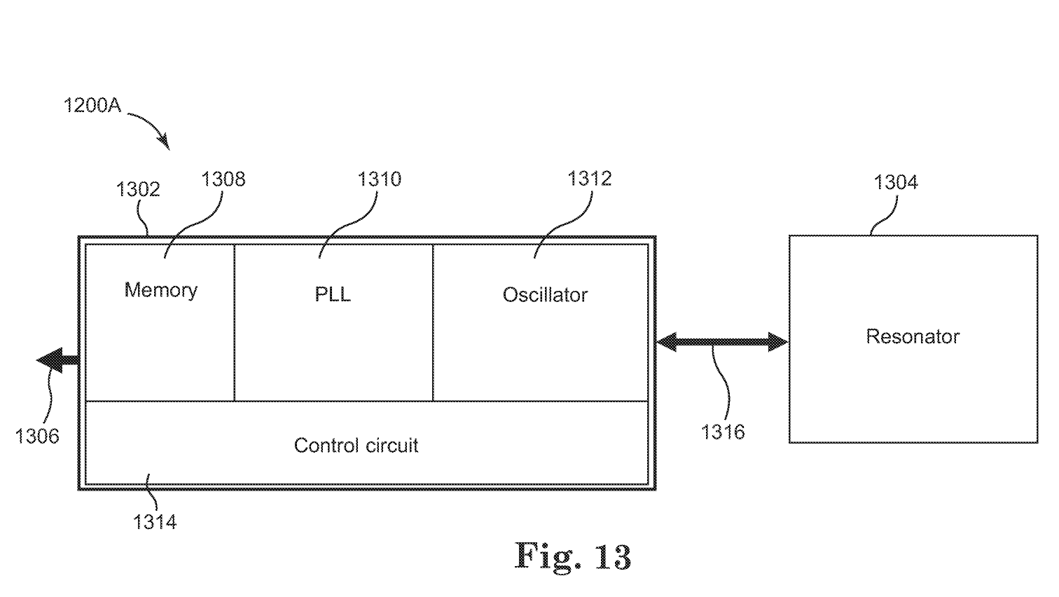

FIG. 13 is a block diagram illustrating components contained in the MEMS device 1200 shown in FIG. 12 according to one embodiment. The embodiment of the MEMS device 1200 shown in FIG. 13 is represented by reference number 1200A. The integrated circuit 602 of MEMS device 1200 is represented in FIG. 13 by CMOS ASIC block 1302, and the resonator of the MEMS device 1200 is represented in FIG. 13 by resonator block 1304. ASIC 1302 is communicatively coupled to resonator 1304 via communication link 1316. As shown in FIG. 13, ASIC 1302 includes memory 1308, phase-locked loop (PLL) 1310, oscillator 1312, and control circuit 1314. Control circuit 1314 controls oscillator 1312 and PLL 1310, and reads data from and writes data to memory 1308. Oscillator 1312 outputs drive signals to resonator 1304 on communication link 1316, and receives sense signals from resonator 1304 on communication link 1316. PLL 1310 provides temperature compensation and trimming of the oscillator signals. ASIC 1302 outputs signals via communication link 1306.

In one embodiment, MEMS device 1200 includes multiple resonators, and a separate control circuit, such as ASIC 1302, is provided for each resonator. In another embodiment, MEMS device 1200 includes multiple resonators, and a single control circuit is provided to control all of the resonators in the device 1200.

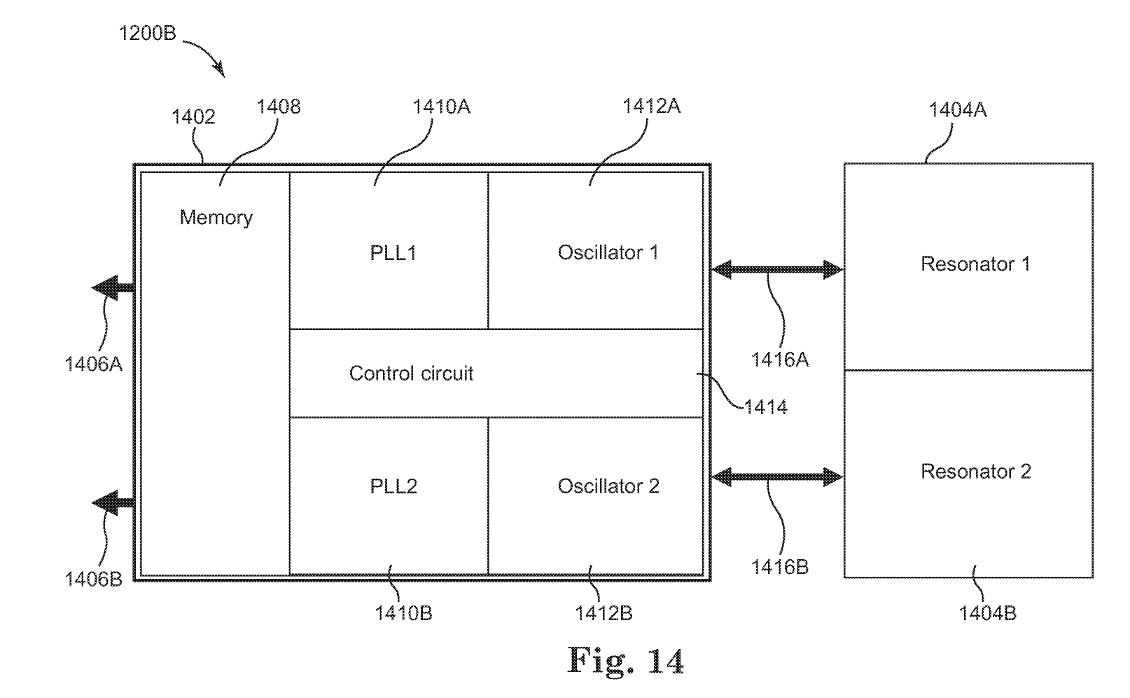

FIG. 14 is a block diagram illustrating components contained in the MEMS device 1200 shown in FIG. 12 according to another embodiment. The embodiment of the MEMS device 1200 shown in FIG. 14 is represented by reference number 1200B. The integrated circuit 602 of MEMS device 1200 is represented in FIG. 14 by CMOS ASIC block 1402, and in the illustrated embodiment, the device 1200 includes a plurality of resonators, which are represented by resonator blocks 1404A and 1404B. ASIC 1402 is communicatively coupled to resonator 1404A via communication link 1416A, and is communicatively coupled to resonator 1404B via communication link 1416B. As shown in FIG. 14, ASIC 1402 includes memory 1408, first PLL 1410A, second PLL 1410B, first oscillator 1412A, second oscillator 1412B, and control circuit 1414. Control circuit 1414 controls oscillators 1412A and 1412B and PLLs 1410A and 1410B, and reads data from and writes data to memory 1408. First oscillator 1412A outputs drive signals to resonator 1404A on communication link 1416A, and receives sense signals from resonator 1404A on communication link 1416A. Second oscillator 1412B outputs drive signals to resonator 1404B on communication link 1416B, and receives sense signals from resonator 1404B on communication link 1416B. First PLL 1410A provides temperature compensation and trimming of the oscillator signals for first oscillator 1412A. Second PLL 1410B provides temperature compensation and trimming of the oscillator signals for second oscillator 1412B. ASIC 1402 outputs signals for resonator 1404A via communication link 1406A, and outputs signals for resonator 1404B via communication link 1406B.

Several advantages are provided by embodiments of the present invention, including: A smaller form factor than other integration solutions; very different process technologies can be used for the two sides of the SOI substrate (e.g., MEMS on one side, and high density Cu-technology on the other side) and single crystal silicon (Si) substrates for both technologies; space and cost savings by avoiding expensive pads typically used in highly integrated technologies; different doping levels for the two sides of the SOI substrate may be used; and improved ESD and EMC performance by avoiding external wiring.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
a silicon-on-insulator (SOI) substrate including a buried oxide layer positioned between a top-side silicon layer and a bottom-side silicon layer;
a micro-electromechanical system (MEMS) device integrated into the top-side silicon layer;
a semiconductor layer formed over the bottom-side silicon layer; and
a control circuit integrated into the semiconductor layer and configured to control the MEMS device.

2. The integrated circuit of claim 1, wherein the MEMS device is a MEMS resonator device.

3. The integrated circuit of claim 2, wherein the MEMS resonator includes a silicon resonator structure formed in the top-side silicon layer, and a plurality of electrodes formed in the top-side silicon layer.

4. The integrated circuit of claim 3, and further comprising:
at least one metal-filled via in contact with at least one of the electrodes, and extending through the buried oxide layer, the bottom-side silicon layer, and the semiconductor layer.

5. The integrated circuit of claim 1, and further comprising:
at least one contact pad positioned adjacent to a bottom-side of the SOI substrate and connected to at least one metal-filled via that extends through the buried oxide layer, the bottom-side silicon layer, and the semiconductor layer.

6. The integrated circuit of claim 1, and further comprising:
at least one contact pad positioned adjacent to a bottom-side of the SOI substrate; and
wherein the integrated circuit includes no contact pads positioned adjacent to a top-side of the SOI substrate.

7. The integrated circuit of claim 1, wherein the top-side silicon layer and the bottom-side silicon layer are each a single crystal silicon layer.

8. The integrated circuit of claim 1, wherein the control circuit comprises an application specific integrated circuit (ASIC).

9. The integrated circuit of claim 1, and further comprising:
a non-conductive layer formed on the top-side silicon layer.

10. The integrated circuit of claim 9, wherein the non-conductive layer is a SiN layer.

11. The integrated circuit of claim 9, and further comprising:
a protective cap layer formed on the non-conductive layer.

12. The integrated circuit of claim 11, wherein the protective cap layer is a Si layer.

13. The integrated circuit of claim 1, wherein the MEMS device and the control circuit are formed using substantially different processing technologies.

14. The integrated circuit of claim 1, wherein the semiconductor layer is an n− doped epitaxial silicon layer.

15. A method of manufacturing an integrated circuit, comprising:
providing a silicon-on-insulator (SOI) substrate;
forming a micro-electromechanical system (MEMS) resonator device in a first silicon layer of the substrate;
forming a control circuit in a second silicon layer, the second silicon layer separated from the first silicon layer by a buried oxide layer, the control circuit configured to control the MEMS resonator device; and
forming at least one metal-filled via that extends through the buried oxide layer, the at least one metal-filled via connecting the MEMS resonator and the control circuit.

16. The method of claim 15, wherein the MEMS resonator includes a silicon resonator structure formed in the first silicon layer, and first and second electrodes formed in the first silicon layer.

17. The method of claim 16, wherein the at least one metal-filled via comprises a first metal-filled via that contacts the first electrode and a second metal-filled via that contacts the second electrode.

18. The method of claim 15, and further comprising:
forming at least one contact pad over the second silicon layer and connected to at least one metal-filled via that extends through the buried oxide layer and the second silicon layer.

19. The method of claim 15, wherein the first silicon layer is a first single crystal silicon layer, and the second silicon layer is an epitaxial silicon layer that is formed over a second single crystal silicon layer of the SOI substrate.

20. The method of claim 15, and further comprising:
forming a second MEMS resonator device in the first silicon layer of the substrate.

21. An integrated circuit, comprising:
a silicon-on-insulator (SOI) substrate;
a micro-electromechanical system (MEMS) resonator device integrated into a top-side silicon layer of the SOI substrate;
a CMOS circuit integrated into a bottom-side silicon layer and configured to control the MEMS resonator device; and
at least one metal-filled via in contact with at least one electrode of the MEMS resonator device, and extending through a buried oxide layer of the SOI substrate and the bottom-side silicon layer.
